(19) United States
(12) Patent Application Publication
(10) Pub. No.: US 2026/0173679 A1
(43) Pub. Date: Jun. 18, 2026

(54) DISPLAY APPARATUS

(71) Applicant: LG Display Co., Ltd., Seoul (KR)

(72) Inventor: Hyunjik BAE, Paju-si (KR)

(73) Assignee: LG Display Co., Ltd., Seoul (KR)

(21) Appl. No.: 19/193,848

(22) Filed: Apr. 29, 2025

(30) Foreign Application Priority Data
Dec. 13, 2024 (KR) 10-2024-0185668

(51) Int. Cl. H10K 59/131; G06F 3/044; H10K 59/121; H10K 59/122; H10K 59/40

(52) U.S. Cl. CPC H10K 59/131; G06F 3/0443; H10K 59/1213; H10K 59/122; H10K 59/40; G06F 2203/04111

(57) ABSTRACT

An embodiment of the present disclosure provides a display device including a substrate including a display area in which a plurality of subpixels is arranged and a non-display area surrounding the display area. A plurality of light emitting elements provided in the display area. A first pad electrode is disposed on the non-display area of the substrate, and a planarization layer is formed to cover an end of the first pad electrode. A pad dam covers an end of the planarization layer may serve to shield the pad structure from external impact or processing stress. A second pad electrode is disposed on the first pad electrode, the planarization layer, and the pad dam. A cushion layer is interposed between the first pad electrode and the second pad electrode to absorb mechanical stress during testing, reduce the likelihood of cracks, and improve the reliability and yield of the display device.

### CROSS-REFERENCE TO RELATED APPLICATION

This application claims the benefit of priority of the Republic of Korea Patent Application No. 10-2024-0185668 filed on Dec. 13, 2024, which is hereby incorporated by reference in its entirety.

### BACKGROUND

### Technical Field

The present disclosure relates to a display device.

### Description of the Related Art

With the advancement of the information society, the field of display devices for displaying images has rapidly developed. Accordingly, display devices are being developed in forms that offer excellent performance in terms of slimness, light weight, and low power consumption.

Among various types of display devices, emissive display devices are self-emissive and do not require a separate light source, making it possible to manufacture them in a lightweight and slim form. Emissive display devices are advantageous in terms of power consumption due to low-voltage driving, and also excel in color reproduction, response speed, viewing angle, and contrast ratio (CR), and are expected to be used in various fields.

### BRIEF SUMMARY

The disclosure provides a display device with improved test pad reliability using a layered structure that includes a cushion layer positioned between a lower first pad electrode and an upper second pad electrode. The cushion layer, composed of an organic material, reduces mechanical stress during lighting tests and helps prevent crack formation, moisture penetration, and static-related defects, thereby improving panel yield. A pad dam is also formed over a planarization layer to cover the edge of the first pad electrode and protect it from contact during deposition processes, such as those involving sagging masks.

This structure supports reliable electrical contact while enhancing physical durability and is compatible with touch on encapsulation configurations. By utilizing shared materials for the pad dam, spacer, and bank, the design allows efficient patterning and process integration. These features collectively contribute to a display device that is more robust against mechanical and environmental damage during manufacturing and testing.

Accordingly, the present disclosure is directed to providing a display device that substantially obviate one or more problems due to limitations and disadvantages of the related art.

The present disclosure provides a display device that reduces or minimizes damage to the test pad.

The present disclosure provides a display device that reduces or minimizes the occurrence of cracks that occur during lighting test.

The present disclosure provides a low-power display device with improved reliability by preventing moisture infiltration and corrosion due to cracks in the test pad.

The problems to be solved according to the embodiments of the present specification are not limited to the problems mentioned above, and other problems not mentioned will be clearly understood by those skilled in the art from the description below.

A display device according to an embodiment of the present specification may include a substrate including a display area in which a plurality of sub-pixels are arranged and a non-display area surrounding the display area, a plurality of light emitting elements arranged in the display area, a plurality of pad electrodes on the substrate arranged in the non-display area, and a plurality of test pads.

Specific details of other embodiments are included in the detailed description and drawings.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a drawing showing a display device according to an embodiment of the present specification.

FIG. 2 is a drawing of area A of FIG. 1.

FIG. 3 is a cross-sectional view taken along line A-A′ of FIG. 1.

FIG. 4 is a drawing of the test pad of FIG. 1 according to an embodiment of the present specification.

FIG. 5 is a cross-sectional view taken along line BB′ of FIG. 4.

FIG. 6 is a cross-sectional view taken along line B-B′ of FIG. 4 according to another embodiment of the present specification.

FIGS. 7A and 7B are a drawing for explaining the application result of an embodiment of the present specification.

### DETAILED DESCRIPTION

The advantages and features of the present specification and the method for achieving them will become clear with reference to the embodiments described in detail below together with the accompanying drawings. However, the present specification is not limited to the embodiments disclosed below, but may be implemented in various different forms, and the present embodiments are provided only to make the disclosure of the present specification complete and to fully inform a person having ordinary skill in the art to which the present specification belongs of the scope of the disclosure, and the present specification is defined only by the scope of the claims.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification. In addition, in describing the present specification, if it is determined that a detailed description of a related known technology may unnecessarily obscure the gist of the present specification, the detailed description will be omitted. When the terms “includes,” “has,” “consists of,” etc., are used in the present specification, other parts may be added unless “only” is used. When a component is expressed in the singular, it includes a case where the plural is included unless there is a specifically explicit description.

When interpreting a component, it is interpreted as including the error range even if there is no separate explicit description of the error range.

When describing a positional relationship, for example, when the positional relationship between two parts is described as “on,” “above,” “below,” “next to,” etc., there may be one or more other parts located between the two parts, unless, for example, “right” or “directly” is used.

When describing a temporal relationship, if the temporal continuity is described as “after,” “following,” “next to,” or “before,” it can also include cases where it is not continuous, as long as “immediately” or “directly” is not used.

Although the terms first, second, etc., are used to describe various components, these components are not limited by these terms. These terms are only used to distinguish one component from another. Thus, a first component referred to below may also be a second component within the technical scope of this specification.

In describing components of this specification, terms such as first, second, A, B, (a), (b), etc., may be used. These terms are only intended to distinguish the components from other components, and the nature, order, sequence, or number of the components are not limited by these terms. When a component is described as being “connected,” “coupled,” or “connected” to another component, it should be understood that the component may be directly connected or connected to the other component, but that other components may also be “interposed” between each component that is indirectly connected or connected without any specifically explicit description.

At least one should be understood to include any combination of one or more of the associated components. For example, the meaning of “at least one of the first, second, and third components” could be taken to include not only the first, second, or third components, but also any combination of two or more of the first, second, and third components.

In this specification, the “display device” may include a narrowly defined display device such as a liquid crystal module (LCM), an organic light emitting diode (OLED) module, and a quantum dot module including a display panel and a driving unit for driving the display panel. In addition, it may also include a set electronic apparatus or a set device or set apparatus such as a notebook computer, a television, a computer monitor, an automotive display apparatus, or other forms of a vehicle, which are complete products or final products including an LCM, an OLED module, and a QD module, and a mobile electronic apparatus such as a smart phone or an electronic pad.

Accordingly, the display device in the present specification may include a narrowly defined display device itself, such as an LCM, an OLED module, and a QD module, and a set device, which is an application product or end-user device including an LCM, an OLED module, and a QD module.

In some cases, an LCM, OLED module, or QD module composed of a display panel and a driver may be expressed as a “display device” in a narrow sense, and an electronic device as a finished product including an LCM, OLED module, or QD module may be expressed as a “set device.” For example, a display device in a narrow sense may include a display panel of liquid crystal display (LCD), organic light emitting diode (OLED), or quantum dot, and a source PCB which is a control unit for driving the display panel, and a set device may further include a set PCB which is a set control unit that is electrically connected to the source PCB and controls the entire set device.

The display panel used in the embodiments of the present specification may be any type of display panel, such as a liquid crystal display panel, an organic light emitting diode (OLED) display panel, a quantum dot (QD) display panel, and an electroluminescent display panel. The display panel of the present embodiment is not limited to a specific display panel capable of bezel bending with a flexible substrate for an organic electroluminescent (OLED) display panel and a back plate support structure at the bottom. In addition, the display panel used in the display device according to the embodiments of the present specification is not limited to the shape or size.

For example, when the display panel is an organic electroluminescent (OLED) display panel, it may include a plurality of gate lines and data lines, and pixels formed in intersection areas of the gate lines and/or data lines. In addition, it may be configured to include an array including a thin film transistor, which is an element for selectively applying voltage to each pixel, a light emitting element layer on the array, and an encapsulation substrate or encapsulation layer disposed on the array to cover the light emitting element layer. The encapsulation layer may protect the thin film transistor, the light emitting element layer, etc., from external impact, and prevent moisture or oxygen from penetrating into the light emitting element layer. In addition, the layer formed on the array may include an inorganic light emitting layer, for example, a nano-sized material layer or a quantum dot.

The individual features of the various embodiments of this specification may be partially or wholly combined or combined with each other, and may be technically interconnected and operated in various ways, and each embodiment may be implemented independently of each other or implemented together in a related relationship.

Hereinafter, examples of the present specification will be described with reference to the attached drawings and examples. The scale of the components illustrated in the drawings is different from the actual scale for convenience of explanation, and is therefore not limited to the scale illustrated in the drawings.

Hereinafter, the present specification will be described with reference to the drawings.

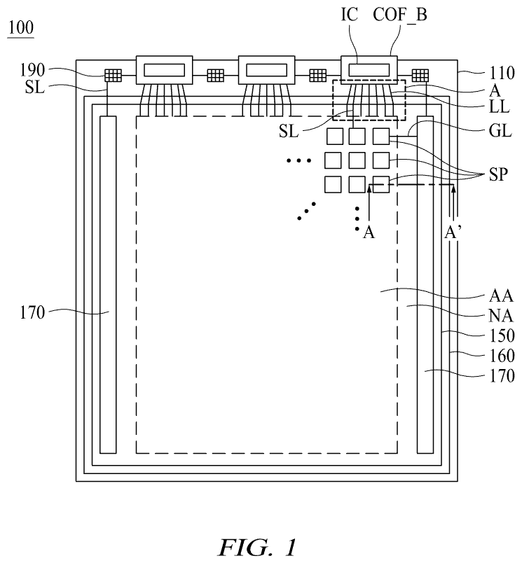

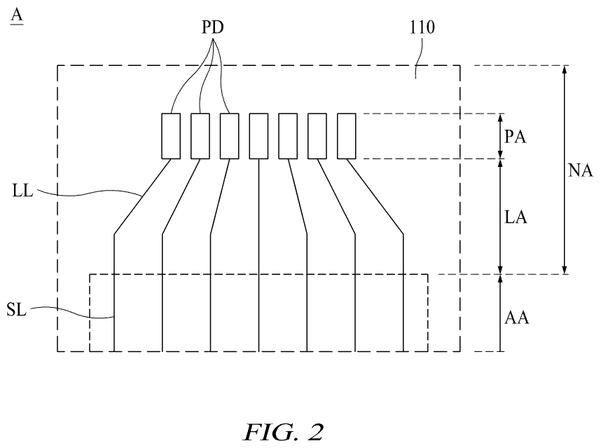

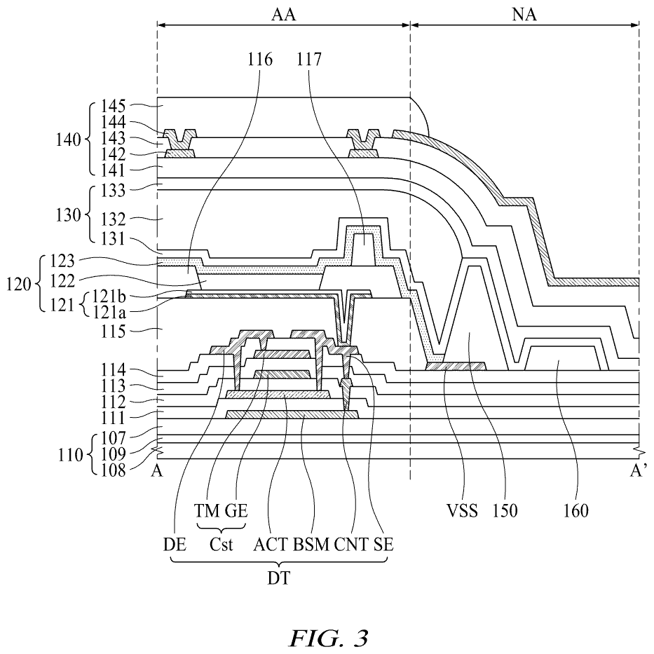

FIG. 1 is a drawing showing a display panel of a display device according to an embodiment of the present specification. FIG. 2 is a plan view showing an enlarged view of area A of FIG. 1. FIG. 3 is a cross-sectional view taken along line A-A′ of FIG. 1.

In FIG. 1, a substrate 110, a sub-pixel SP, a link wiring LL, and a circuit film COF, which are some of the various components of a display panel 100 of a display device, are illustrated, and in FIG. 2, the illustration of the circuit film COF is omitted.

Referring to FIGS. 1 and 2, a display panel 100 of a display device according to one embodiment of the present specification may include a substrate 110, a signal line SL, a link line LL, a pad electrode PD, and a circuit film COF.

Referring to FIG. 3 together, the substrate 110 may include a first substrate 107, an interlayer insulating layer 109, and a second substrate 108.

The first substrate 107 and the second substrate 108 may be substrates that support components placed on the substrate 110, and may be insulating substrates. For example, the first substrate 107 and the second substrate 108 may be made of glass or resin, etc. For example, the first substrate 107 and the second substrate 108 may be made of a polymer or plastic. In some embodiments, the first substrate 107 and the second substrate 108 may be made of a plastic material having flexibility.

An interlayer insulating layer 109 may be placed between the first substrate 107 and the second substrate 108. The interlayer insulating layer 109 may include an inorganic material to protect the first substrate 107 and the second substrate 108 from moisture penetration. The embodiments of the present specification are not limited thereto.

A plurality of pixels may be formed on the substrate 110 so that an image may be displayed. The substrate 110 may include a display area AA and a non-display area NA surrounding the display area AA.

The display area AA may be an area on the display panel 100 of the display device where an image is displayed. In the display area AA, a plurality of sub-pixels SP constituting a plurality of pixels and a plurality of signal lines SL for driving the plurality of sub-pixels SP may be arranged. The plurality of sub-pixels SP may be the minimum units constituting the display area AA, and n sub-pixels SP may form one pixel. A light emitting element and a thin film transistor for driving the light emitting element may be arranged in each of the plurality of sub-pixels SP. The plurality of light emitting elements may be defined differently depending on the type of the display panel. For example, the light emitting element may be an OLED (Organic Light emitting Diode). The light emitting element may include, for example, an inorganic light emitting element (micro LED), and the embodiments of the present specification are not limited thereto.

The plurality of signal lines SL may extend from the display area AA to the non-display area NA and be electrically connected to the pad electrode PD. The plurality of signal lines SL may be respectively connected to a plurality of sub-pixels SP to transmit various signals. The plurality of signal lines SL may be, for example, gate lines, data lines, power lines, or scan lines, but are not limited thereto.

The non-display area NA may be an area where the image is not displayed and may be defined as an area extending from the display area AA. The non-display area NA may include a link area LA and a pad area PA.

The link area LA may be arranged between a display area AA and a pad area PA. The link area LA is an area where link lines LL for transmitting signals to signal lines SL arranged between the display areas AA are arranged, and various link lines LL may be arranged. The plurality of link lines LL may be respectively connected to a plurality of pad electrodes PD of the pad area PA. The plurality of link lines LL may be, for example, gate link lines, data link lines, power link lines, and power supply lines, but are not limited thereto.

The pad area PA does not display an image, and a plurality of pad electrodes PD may be arranged. The pad area PA may be an area in which lines are extends from one side of the link area LA. The pad area PA may be an area where, for example, a power supply pad, a data pad electrode, and a gate pad electrode are arranged.

On one side of the non-display area NA, an test pad (AP PAD) 190 may be placed to perform an auto probe test to check the normal operation of the display panel after the display panel is manufactured. The test pad 190 may be a lighting pad or an AP pad. The test pad 190 may be placed adjacent to the pad section. Through a process such as contacting an test needle to the test pad 190 and then applying an electrical test signal, the test signal is applied to the display panel through test lines connected to the test pad 190.

In an embodiment, a circuit film COF on which a driving chip IC is mounted to transmit signals to the sub-pixels SP of a display area AA may be placed in a non-display area NA. The circuit film COF may include a base film COF_B, a driving chip IC, and a pad portion.

The base film COF_B may be a layer that supports the circuit film COF. The base film COF_B may be made of an insulating material, and may be made of an insulating material having flexibility, for example.

The driving chip IC may be a component that processes data for displaying an image and a driving signal for processing the data, and may be electrically connected to the substrate 110 through a pad portion. The driving chip IC may be mounted in a chip on film COF method, but is not limited thereto.

The test pad 190 may be placed at an edge of the non-display area NA. For example, the test pad 190 may be placed on both sides of the non-display area NA. For example, the test pad 190 may be placed adjacent to one side of the circuit film COF. For example, the test pads 190 may be placed adjacent to each other with the circuit film COF interposed therebetween.

The pad portion may supply power voltage, data voltage, etc., to multiple pixels SP of the display area AA through pad electrodes PD arranged in the pad area PA. The pad portion may be made of a conductive material such as copper (Cu), but is not limited thereto.

A gate driver 170 that provides a gate signal to a thin film transistor may be placed on the other side of the non-display area NA. The gate driver 170 may include various gate driving circuits, and the gate driving circuits may be disposed directly on the substrate 110.

A prevention structure 150 may be arranged in a non-display area NA to surround all or part of the display area AA. For example, the prevention structure 150 may be a dam DAM. The prevention structure 150 may be arranged adjacent to the display area AA and further outside the display area AA.

A panel crack detector 160 may be further arranged on a portion of the non-display area NA of the substrate 110. The panel crack detector 160 may be arranged between the end point (or end) of the substrate 110 and the prevention structure 150. In an embodiment, the panel crack detector 160 may be arranged below the prevention structure 150 and may overlap at least partially with the prevention structure 150. The embodiments of the present specification are not limited thereto.

Referring to FIG. 3, a light shielding layer BSM may be disposed on the substrate 110. The light shielding layer BSM may block light incident on the active layer ACT of a plurality of transistors to reduce or minimize leakage current. For example, the light shielding layer BSM may be disposed under the active layer ACT of the transistor DT to block light incident on the active layer ACT. For example, when light is irradiated on the active layer ACT, leakage current may occur, which may deteriorate the reliability of the transistor DT. Therefore, a light shielding layer BSM that blocks light may be disposed on the substrate 110 to improve the reliability of the transistor DT. The light shielding layer BSM may be composed of an opaque conductive material, for example, copper (Cu), aluminum (Al), molybdenum (Mo), nickel (Ni), titanium (Ti), chromium (Cr), or an alloy thereof, but is not limited thereto.

The buffer layer 111 may be disposed on the light shielding layer BSM. The buffer layer 111 may reduce the penetration of moisture or impurities through the substrate 110. The buffer layer 111 may be composed of, for example, a single layer or multiple layers of silicon oxide (SiOx) or silicon nitride (SiNx), but is not limited thereto. However, the buffer layer 111 may be omitted depending on the type of the substrate 110 or the type of the transistor DT, and is not limited thereto.

A transistor DT including an active layer ACT, a gate electrode GE, a source electrode SE, and a drain electrode DE may be placed on a buffer layer 111.

For example, an additional buffer layer may be disposed between the substrate 110 and the light shielding layer BSM. The additional buffer layer may be composed of, for example, a single layer or multiple layers of silicon oxide (SiOx) or silicon nitride (SiNx) to reduce the penetration of moisture or impurities through the substrate 110 in the same manner as the buffer layer 111 described above, but is not limited thereto.

First, an active layer ACT of a transistor DT may be disposed on a buffer layer 111. The active layer ACT may be made of a semiconductor material such as an oxide semiconductor, amorphous silicon, or polysilicon, but is not limited thereto.

For example, other transistors such as a switching transistor, a sensing transistor, a light emitting control transistor, etc., other than the transistor DT may be additionally arranged, and the active layer of these transistors may also be made of a semiconductor material such as an oxide semiconductor, amorphous silicon, or polysilicon, but is not limited thereto.

For example, the active layers of transistors included in a pixel circuit, such as a transistor DT, a switching transistor, a sensing transistor, and a light emitting control transistor, may be made of the same material or may be made of different materials.

A first insulating layer 112 may be disposed on the active layer ACT. The first insulating layer 112 may be, for example, a gate insulating layer, and may be an insulating layer for electrically insulating the active layer ACT and the gate electrode GE. The first insulating layer 112 may be composed of a single layer or multiple layers of silicon oxide (SiOx) or silicon nitride (SiNx), but is not limited thereto.

A gate electrode GE may be placed on the first insulating layer 112. The gate electrode GE may be composed of a conductive material, such as, but not limited to, copper (Cu), aluminum (Al), molybdenum (Mo), nickel (Ni), titanium (Ti), chromium (Cr), or an alloy thereof.

For example, a connection electrode CNT may be disposed on the first insulating layer 112. The connection electrode CNT may be made of the same material as the gate electrode GE and may be electrically connected to the source electrode SE and the light shielding layer BSM.

A first interlayer insulating layer 113 and a second interlayer insulating layer 114 may be disposed on the gate electrode GE. Contact holes are formed in the first interlayer insulating layer 113 and the second interlayer insulating layer 114 for connecting the source electrode SE and the drain electrode DE to the active layer ACT, respectively. The first interlayer insulating layer 113 and the second interlayer insulating layer 114 are insulating layers for protecting the underlying structure, and may be formed of a single layer or multiple layers of silicon oxide (SiOx) or silicon nitride (SiNx), but are not limited thereto.

A storage capacitor Cst may be disposed on the first insulating layer 112. The storage capacitor Cst may be implemented using the middle electrode TM and the gate electrode GE as capacitor electrodes, but is not limited thereto and may be implemented in various ways.

The intermediate electrode TM may be disposed on the first interlayer insulating layer 113. The intermediate electrode TM may be disposed to overlap the gate electrode GE with the first interlayer insulating layer 113 therebetween.

A source electrode SE and a drain electrode DE electrically connected to an active layer ACT may be disposed on a second interlayer insulating layer 114. The drain electrode DE may be electrically connected to a storage capacitor Cst, and the source electrode SE may be connected to a first electrode 121 of a light emitting element 120. The source electrode SE and the drain electrode DE may be composed of a conductive material, for example, copper (Cu), aluminum (Al), molybdenum (Mo), nickel (Ni), titanium (Ti), chromium (Cr), or an alloy thereof, but are not limited thereto.

A planarization layer 115 may be disposed on the source electrode SE and the drain electrode DE. The planarization layer 115 may planarize the upper portion of the pixel circuit including the transistor DT. The planarization layer 115 may be composed of a single layer or multiple layers, and may be made of, for example, benzo-cyclobutene or an acryl organic material, but is not limited thereto.

A plurality of light emitting elements 120 may be arranged in each of a plurality of sub-pixels SP on a planarization layer 115. The light emitting elements 120 may be elements that emit light by current, and may include a red light emitting element that emits red light, a green light emitting element that emits green light, and a light emitting element that emits blue light, and a combination of these may implement light of various colors, including white. For example, the light emitting element 120 may be an organic light emitting diode, but is not limited thereto.

The light emitting element 120 may include a first electrode 121, a light emitting layer 122, and a second electrode 123.

The first electrode 121 may be placed on the planarization layer 115. The first electrode 121 may include a reflective layer 121a and a transparent conductive layer 121b. For example, a transparent conductive layer 121b may be placed on the reflective layer 121a. The reflective layer 121a and the transparent conductive layer 121b are layers for supplying holes to the light emitting layer 122 and may be formed of a conductive material having a high work function. The reflective layer 121a may be formed of a laminated structure of an alloy of silver (Ag), palladium PD, and copper (Cu), which are metal materials having a high reflectivity, for example, but is not limited thereto. The transparent conductive layer 121b may be made of, for example, indium-tin-oxide (ITO), which is a transparent conductive oxide (TCO), but is not limited thereto.

A bank 116 may be disposed on the first electrode 121 and the planarization layer 115. The bank 116 may cover the edge of the first electrode 121 of the light emitting element 120 to define a light emitting area. For example, the bank 116 may partition a plurality of sub-pixels SP. The bank 116 may be made of an insulating material to insulate the first electrodes 121 of adjacent sub-pixels SP from each other. For example, the bank 116 may be made of a black bank including a black material having a high light absorption rate to prevent color mixing between adjacent sub-pixels SP. For example, the bank 116 may be made of a black bank to which a black pigment is added to reduce light reflection, but the embodiments of the present specification are not limited thereto.

The bank 116 may be made of at least one of an inorganic insulating material such as silicon nitride (SiNx) or silicon oxide (SiOx), or an organic insulating material such as benzo-cyclobutene (BCB), an acryl resin, an epoxy resin, a phenolic resin, a polyamide resin, or a polyimide resin, for example, and the embodiments of the present specification are not limited thereto.

A spacer 117 may be disposed on the bank 116. The spacer 117 is a layer for maintaining a certain distance between the deposition mask and the bank 116 to prevent damage due to contact with the deposition mask. The spacer 117, like the bank 116, may be made of polyimide resin, acryl resin, or benzo-cyclobutene (BCB) resin, but is not limited thereto. In FIG. 3, the bank 116 and the spacer 117 are separately illustrated, but in an embodiment, the spacer 117 may be formed of the same material as the bank 116, and the bank 116 and the spacer 117 may be simultaneously formed in one process. The embodiments of the present specification are not limited thereto.

For example, the spacer 117 may reduce or minimize damage to the display device from external impact by buffering the empty space between the substrate (101) on which the light emitting element 120 is formed and the upper substrate.

A light emitting layer 122 may be disposed on the first electrode 121. The light emitting layer 122 is a layer in which electrons and holes combine to emit light.

A second electrode 123 may be disposed on the light emitting layer 122. The second electrode 123 may be made of a metal material having a low work function in order to smoothly supply electrons to the light emitting layer 122. The second electrode 123 may be made of a metal material selected from, for example, calcium (Ca), barium (Ba), aluminum (Al), silver (Ag), and an alloy including at least one of these, but is not limited thereto.

In order to improve the light emitting efficiency of the light emitting element 120, a hole injection layer, a hole transport layer, an electron transport layer, an electron injection layer, etc., may be further included. For example, a hole injection layer and a hole transport layer may be disposed between the first electrode 121 and the light emitting layer 122, and an electron transport layer and an electron injection layer may be disposed between the light emitting layer 122 and the second electrode 123. In addition, a hole-blocking layer or an electron-blocking layer may be disposed to further improve the recombination efficiency of holes and electrons in the light emitting layer 122.

An encapsulating layer 130 may be disposed on the light emitting element 120. The encapsulating layer 130 may protect the light emitting element 120 from external moisture, oxygen, impact, etc. The encapsulating layer 130 may be formed of a multilayer structure in which an inorganic layer made of an inorganic insulating material and an organic layer made of an organic material are laminated. The encapsulating layer 130 may be formed of, for example, at least one organic layer and at least two inorganic layers, and may be a multilayer structure in which the inorganic layers and the organic layers are alternately laminated, but is not limited thereto. The encapsulating layer 130 may be formed of, for example, a triple-layer structure including a first inorganic encapsulating layer 131, an organic encapsulating layer 132, and a second inorganic encapsulating layer 133. At this time, the first inorganic sealing layer 131 and the second inorganic sealing layer 133 may each be independently made of at least one selected from among silicon nitride (SiNx), silicon oxide (SiOx), aluminum oxide (AlOx), and silicon oxynitride (SiON), but are not limited thereto. For example, the organic sealing layer 132 may be made of at least one selected from among epoxy resin, polyimide resin, polyethylene resin, and silicon oxycarbide (SiOC), but are not limited thereto.

A touch detection unit 140 for recognizing a user's touch may be disposed on the encapsulation layer 130. The touch detection unit 140 may include a touch buffer layer 141, a touch bridge electrode 142, a touch insulation layer 143, a touch electrode 144, and a touch protection layer 145.

A touch buffer layer 141 may be arranged on the sealing layer 130. The touch buffer layer 140 is a layer for preventing damage to the light emitting element 120 and the sealing layer 130, and may be formed of an inorganic material having excellent barrier properties. Accordingly, penetration of moisture or oxygen may be reduced or minimized. The touch buffer layer 141 may be formed of, for example, a single layer or multiple layers of silicon nitride (SiNx) or silicon oxide (SiOx), but is not limited thereto.

A touch bridge electrode 142 may be disposed on the touch buffer layer 141. The touch bridge electrode 142 may connect a touch electrode 144.

A touch insulation layer 143 may be disposed on the touch buffer layer 141 and the touch bridge electrode 142. The touch insulation layer 143 may be a layer for insulating the touch bridge electrode 142 and the touch electrode 144 and may be made of an inorganic material. The touch insulation layer 143 may be composed of a single layer or multiple layers of, for example, silicon oxide (SiOx) or silicon nitride (SiNx), but is not limited thereto.

A touch electrode 144 may be disposed on the touch insulation layer 143. The touch electrode 144 is an electrode that detects a touch input and may be composed of a sensing electrode and a driving electrode, and may detect a touch coordinate by detecting a capacitance change therebetween. The touch electrode 144 may be made of a transparent metal material such as indium-tin-oxide (ITO) or indium-zinc-oxide (IZO) that may transmit light, but is not limited thereto.

For example, a touch electrode 144 may be disposed on a touch insulating layer 143. A touch line 146 may electrically connect the touch electrode 144 and the touch circuit. The touch line 146 may be disposed on the same layer as the touch electrode 144, but is not limited thereto.

A touch protection layer 145 may be disposed on the touch electrode 144. The touch protection layer 145 is a layer for preventing short circuits or damage to the touch electrode 144 and for flattening the upper surface of the touch electrode 144. The touch protection layer 145 may be made of a transparent insulating resin, such as an acryl resin, a polyester resin, or an epoxy resin, but is not limited thereto.

For example, a power line VSS connected to a second electrode 123 may be placed in a non-display area NA. The power line VSS may be electrically connected to the second electrode 123 of the light emitting element 120 to apply a power voltage to the light emitting element 120.

A prevention structure 150 may be arranged on the power wiring VSS. The prevention structure 150 is arranged to control overflow of the organic sealing layer 132 among the sealing layers 130. The prevention structure 150 may include a lower layer made of the same material as the planarization layer 115 and an upper layer made of the same material as the bank 116, but is not limited thereto, and may be formed of three or more layers. In addition, although only one prevention structure 150 is illustrated in FIG. 3, the prevention structure 150 may be two or more, and is not limited thereto. The sealing layer 130, the touch buffer layer 141, and the touch insulation layer 143 may be disposed on the upper portion of the prevention structure 150.

The crack prevention layer 160 may be disposed on the outside of the prevention structure 150. The crack prevention layer 160 may serve as a buffer against external impact to prevent cracks from propagating to the display area AA. Accordingly, the crack prevention layer 160 may be made of an organic insulating material having high strain and impact resistance. The crack prevention layer 160 may be made of, for example, the same material as the planarization layer 115 or the bank 116, but is not limited thereto.

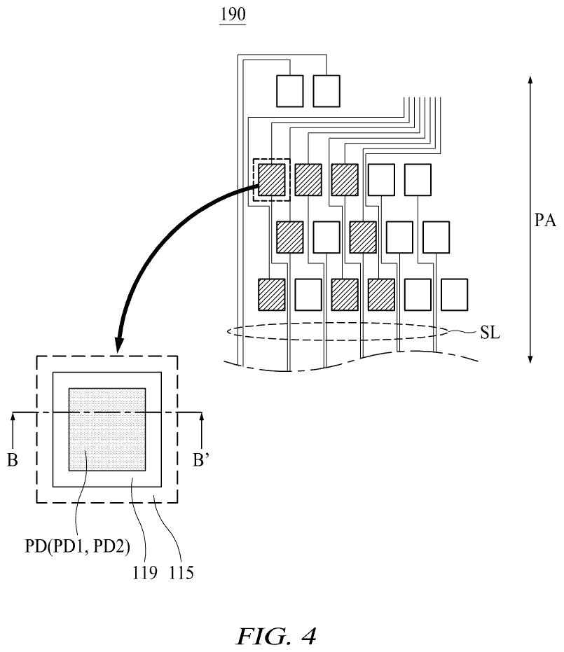

Hereinafter, the test pad 190 of the display panel 100 of the display device according to one embodiment of the present specification will be described in detail with reference to FIGS. 4 to 6.

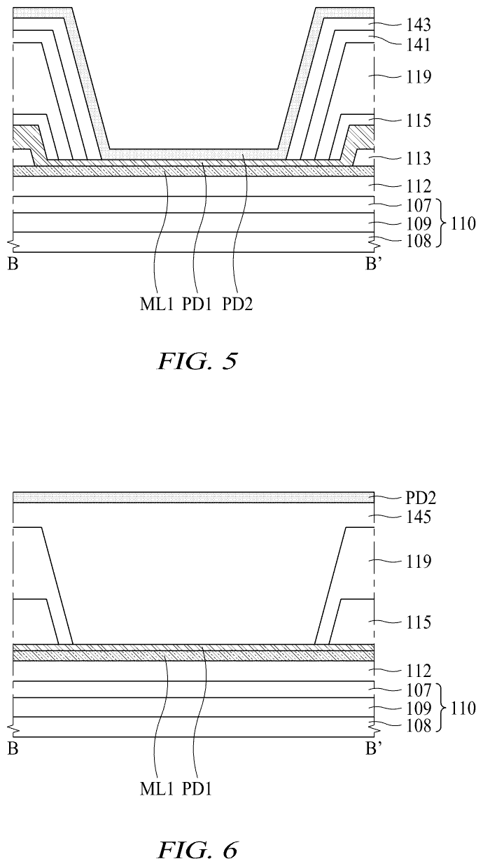

FIG. 4 is a drawing showing the test pad 190 of FIG. 1. FIG. 5 is a cross-sectional view taken along line B-B′ of FIG. 4. FIG. 6 is a cross-sectional view taken along line B-B′ of FIG. 4 according to another embodiment of the present specification.

Referring to FIGS. 1 and 4, the pad area PA may include a test pad 190. For example, the test pad 190 may include a first pad electrode PD1.

For example, a signal line SL may be extended from a test pad 190 and connected to gate drivers 170 arranged on both sides of the display area AA. A gate line (GL) may be extended from a gate driver 170 arranged on the side of the display area AA to the display area AA and connected to each other.

Referring to FIG. 5, a first insulating layer 112 may be disposed on a substrate 110. A first metal layer ML1 may be disposed on the first insulating layer 112. The first metal layer ML1 may be electrically connected to a first pad electrode PD1 to transmit a signal to a display area AA. The first metal layer ML1 may be made of the same material as a gate electrode GE of a transistor DT, but embodiments are not limited thereto.

A first interlayer insulating layer 113 may be disposed on the first metal layer ML1.

A first pad electrode PD1 may be disposed on a first interlayer insulating layer 113. The first pad electrode PD1 may transmit a signal to a plurality of sub-pixels SP or be electrically connected to a printed circuit board. An edge of the first pad electrode PD1 may be covered by a planarization layer 115. For example, the planarization layer 115 may cover the edges of the plurality of first pad electrodes PD1. For example, the first pad electrode PD1 may be disposed on the same layer as a source electrode SE and a drain electrode DE of the transistor DT and may be made of the same material as the source electrode SE and the drain electrode DE.

In an embodiment, a pad dam 119 may be disposed on the planarization layer 115. For example, at least one pad dam 119 may cover an end of the planarization layer 115.

For example, one end of at least one pad dam 119 may be placed on the planarization layer 115, and the other end of at least one pad dam 119 may cover an end of the planarization layer 115.

An insulating layer may be disposed on the pad dam 119 to cover the pad dam 119. The insulating layer may include a touch buffer layer 141 and a touch insulation layer 143. For example, a second pad electrode PD2 among the pad electrodes may be disposed on the touch buffer layer 141 and the touch insulation layer 143.

For example, the touch buffer layer 141 and the touch insulation layer 143 may be positioned to expose a portion of the first pad electrode PD1 for connection between the first pad electrode PD1 and the second pad electrode PD2.

For example, a second pad electrode PD2 may be disposed on a first pad electrode PD1. For example, a part of the second pad electrode PD2 may be disposed such that the upper surface of the first pad electrode PD1 and the lower surface of the second pad electrode PD2 are in contact.

The second pad electrode PD2, like the first pad electrode PD1, may transmit signals to a plurality of sub-pixels SP or be electrically connected to a printed circuit board. For example, the second pad electrode PD2 may be connected to the first pad electrode PD1 through a contact hole of the touch buffer layer 141 and the touch insulation layer 143. The second pad electrode PD2 may be disposed in the same layer as one of the touch bridge electrode 142 and the touch electrode 144 and may be made of the same material, but the embodiments are not limited thereto.

Referring to FIG. 5, according to an embodiment of the present specification, the first pad electrode PD1 may have different double thicknesses. For example, the thickness of the center of the first pad electrode PD1 in contact with the first metal layer ML1 may be thinner than the thickness of the end of the first pad electrode PD1 that does not contact the first metal layer ML1. For example, the thickness of the end of the first pad electrode PD1 may be thicker than the thickness of the center of the first pad electrode PD1. For example, the center of the first pad electrode PD1 may be in contact with the test contact pin. For example, the end of the first pad electrode PD1 may be an area overlapping the planarization layer 115 and/or the pad dam 119. For example, the thickness of the central portion of the first pad electrode PD1 may be reduced by an etching process (e.g., dry etch) to increase the distance from the first pad electrode PD1 to the mask, thereby protecting the first pad electrode PD1 from mask impression. The first pad electrode PD1 may have the same thickness at the end and the same thickness at the center, and the embodiments of the present specification are not limited thereto.

In an embodiment, the pad dam 119 may include a black material. For example, when a black bank is arranged to prevent color mixing between sub-pixels SP in the display area AA or to reduce reflectivity, the pad dam 119 may be configured as a black bank. The embodiments of the present specification are not limited thereto.

Although not shown in the drawing, a circuit film COF may be disposed on the second pad electrode PD2, so that the pad portion of the circuit film COF may be electrically connected to the second pad electrode PD2 through a conductive adhesive layer ACF. A conductive adhesive layer ACF may be disposed on the plurality of second pad electrodes PD2 to bond the plurality of second pad electrodes PD2 and the circuit film COF. The conductive adhesive layer ACF may be in a state where conductive balls used for adhesion and electrical connection are dispersed in a resin.

In the display device according to the embodiment of the present specification, if the light emitting layer is an organic layer, the light emitting layer may be formed by a thermal deposition method using a mask. For example, a fine metal mask (FMM) may be used to separately form light emitting layers disposed in each of a red sub-pixel, a green sub-pixel, and a blue sub-pixel. For example, the display device may have a printing defect on the pad electrode due to sagging of the fine metal mask.

For example, in a display device in which a touch detection unit is arranged on an encapsulation layer (Touch on Encapsulation; ToE), pad electrode imprinting may be a greater problem. The touch bridge electrode is formed through a deposition process, a photolithography process, and an etching process. If the etching process is performed while the first pad electrode PD1 is imprinted due to mask sagging, the touch insulating layer 143 may be over-etched, exposing the pad electrode. For example, the exposed pad electrode may act as a lightning rod, causing an arcing phenomenon. If an arcing phenomenon occurs, a large current flowing into the pad electrode may flow into the interior of the display device along the pad electrode, causing static electricity to be generated, which may cause a defect in the display device. Accordingly, in a display panel 100 of a display device according to one embodiment of the present specification, a pad dam 119 is disposed on a planarization layer 115 among a plurality of first pad electrodes PD1, so that even if mask sagging occurs, the mask first contacts the pad dam 119, thereby preventing the first pad electrode PD1 from being impressed by the mask.

According to an embodiment of the present specification, the thickness of the pad dam 119 may be thicker than the thickness of the planarization layer 115. The thickness of the pad dam 119 may be thicker than the thickness of the first pad electrode PD1. For example, the pad dam 119 may surround the planarization layer 115. In an embodiment, at least one pad dam 119 is arranged to cover an end of the planarization layer 115, thereby reducing an upper area of the first pad electrode PD1, thereby effectively protecting the first pad electrode PD1. For example, the pad dam 119 may be disposed on the planarization layer 115 in an island-like shape, thereby protecting a plurality of first pad electrodes PD1 from mask impression. In the pad area PA, the end of the pad dam 119 may be closer to the center of the first metal layer ML1 and/or the pad electrode (PD1, PD2) than the end of the planarization layer 115.

In a display panel 100 of a display device according to one embodiment of the present specification, a pad dam 119 is disposed on a plurality of first pad electrodes PD1, thereby reducing or minimizing exposure of the first pad electrodes PD1, preventing current from flowing into the first pad electrodes PD1 due to mask printing, thereby reducing or minimizing static electricity and preventing an arcing phenomenon, thereby improving reliability.

In an embodiment, the pad dam 119 may be an organic material to prevent the mask from being stamped.

For example, the pad dam 119 may include the same material as the bank 116 and spacer 117 of the display area AA.

For example, the pad dam 119 may comprise the same material as the bank 116 of the display area AA.

For example, the pad dam 119 may include the same material as the spacer 117 of the display area AA. Embodiments of the present specification are not limited thereto.

For example, by arranging the bank 116 and/or the spacer 117 of organic materials in a dam (or island) shape on the pad electrode PD1 so that the upper part of the pad dam 119 supports the mask, the problem of the mask touching the first pad electrode PD1 may be improved. The height of the pad dam 119 may be higher than the height of the planarization layer 115.

Referring to FIGS. 4 to 6, the plane shape of the test pad 190 is exemplified as a square shape, but is not limited thereto and may be applied in various shapes such as circular and hexagonal.

The test pad 190 may be a pad for lighting test (Auto probe: AP). The lighting test may be an auto probe test. The lighting test supplies a test voltage to the lighting test pad connected to the signal lines of the display panel 100 through the test contact pin to drive the sub-pixels SP of the display panel 100. The test signal supplied through the pad is connected to each line and applied to the sub-pixel. The lighting test is a test performed in the display panel 100 state before the module process is performed to check whether the sub-pixels are properly lit. Through the lighting test, it is possible to check whether a lighting defect occurs at the completion stage of the display panel 100. Since it is possible to check whether the display panel 100 is defective before the module process is performed, it is possible to prevent in advance various component losses and manufacturing process losses that occur when a defective panel is input into the module process.

FIG. 6 is a drawing of B-B′ of the test pad of FIG. 1 as another embodiment of the present specification. The description of the overlapping portion compared to FIG. 5 will be omitted. Referring to FIG. 6, in the embodiment of the present specification, by arranging a planarization layer 115, a pad dam 119, and a cushion layer 145 between the first pad electrode PD1 and the second pad electrode PD2, the first pad electrode PD1 may be effectively protected from mask impression. The embodiments of the present specification are not limited thereto.

For example, referring to FIG. 6, the pad dam 119 may be placed on the first metal layer ML1 and/or the first pad electrode PD1.

For example, the planarization layer 115 may be disposed on the first metal layer ML1 and/or the first pad electrode PD1.

The cushion layer 145 may be disposed on the first metal layer ML1 and/or the first pad electrode PD1 and/or the planarization layer 115 and/or the pad dam 119.

In an embodiment, the pad dam 119 may include a black material. For example, when a black bank is arranged to prevent color mixing between sub-pixels SP in the display area AA or to reduce reflectivity, the pad dam 119 may be configured as a black bank. The embodiments of the present specification are not limited thereto.

Referring to FIG. 6, according to another embodiment of the present specification, a cushion layer 145 may be formed between the first pad electrode PD1 and the second pad electrode PD2. The cushion layer 145 may be made of the same organic material as the organic encapsulating layer of FIG. 3, but the embodiments are not limited thereto. For example, the cushion layer 145 may be made of at least one selected from an epoxy resin, a polyimide resin, a polyethylene resin, and silicon oxycarbide (SiOC), but is not limited thereto.

The cushion layer 145 may reduce crack propagation caused by the force applied to the pad electrode by the test contact pin during a lighting test.

Since crack propagation that occurs after lighting test is prevented by the cushion layer 145, a design that is robust against moisture penetration and overall corrosion due to cracks may be made possible.

The yield may be improved by preventing panel defects caused by corrosion and cracks by the cushion layer 145.

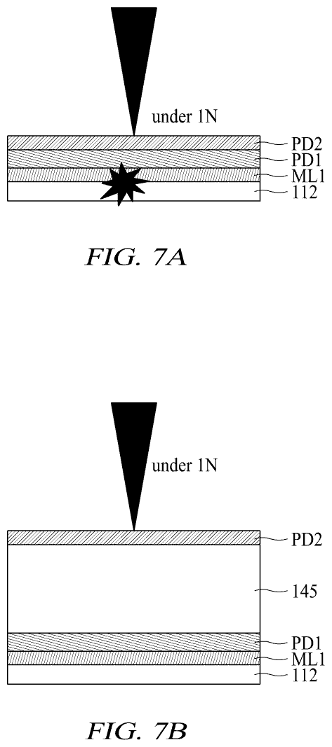

FIGS. 7A and 7B are a drawing for explaining the application result of another embodiment of the present specification.

Referring to FIGS. 7A and 7B, the effect of the case where the cushion layer 145 is disposed between the first pad electrode PD1 and the second pad electrode PD2 in another embodiment of the present specification will be compared and explained with the case where the cushion layer 145 is disposed, so that the effect of the case where the cushion layer 145 is disposed may be understood.

Referring to FIG. 7A, when a cushion layer 145 is not arranged between the first pad electrode PD1 and the second pad electrode PD2, when the force applied to the test pad electrode PD2 of the test contact pin during the lighting test is 1N, the thickness of the test pad electrode PD2 is 6000 Å, the thickness of the first pad electrode PD1 is 6000 Å, the thickness of the metal layer ML1 is 2500 Å, and the distance d reached by the force of the contact pin applied to the insulating layer is 14500 Å.

Referring to FIG. 7B, where a cushion layer 145 is disposed between the first pad electrode PD1 and the second pad electrode PD2, when the force applied to the test pad electrode PD2 of the test contact pin during the lighting test is 1N, the thickness of the test pad electrode PD2 is 6000 Å, the thickness of the cushion layer 145 is 10 um (100000 Å), the thickness of the first pad electrode PD1 is 6000 Å, the thickness of the metal layer ML1 is 2500 Å, and the distance d reached by the force of the contact pin applied to the insulating layer is 114500 Å.

Since the force applied by the contact pin to the insulating layer is inversely proportional to the distance d, and the distance d=114,500 Å when the cushion layer 145 is provided compared to d=14,500 Å when the cushion layer 145 is not provided, it can be seen that the force applied by the contact pin to the insulating layer in the case of FIG. 7B with the cushion layer 145 is reduced by more than 7.9 times compared to the case of FIG. 7A without the cushion layer 145.

In this way, the cushion layer 145 may reduce crack propagation caused by the force applied to the pad electrode by the test contact pin during a lighting test.

Since crack propagation that occurs after lighting test is prevented by the cushion layer 145, a design that is robust against moisture penetration and overall corrosion due to cracks may be made possible.

The cushion layer 145 can prevent panel defects caused by corrosion and cracks, thereby improving yield.

The display device according to an embodiment of the present specification may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical device, a desktop PC, a laptop PC, a netbook computer, a workstation, a navigation system, a vehicle navigation system, a vehicle display device, a vehicle device, a theater device, a theater display device, a television, a wallpaper device, a signage device, a game device, a notebook, a monitor, a camera, a camcorder, and home appliances. And, the display device of this specification may be applied to an organic light emitting lighting device or an inorganic light emitting lighting device.

The display device according to an embodiment of the present specification may be described as follows.

A display device according to an embodiment of the present specification may include a substrate including a display area in which a plurality of subpixels are arranged and a non-display area surrounding the display area, a plurality of light emitting elements provided in the display area, a first pad electrode disposed on the non-display area of the substrate, a planarization layer covering an end of the first pad electrode, a pad dam covering an end of the planarization layer, a second pad electrode disposed on the first pad electrode, the planarization layer, and the pad dam, and a cushion layer disposed between the first pad electrode and the second pad electrode.

A display device according to an embodiment of the present specification further includes a plurality of transistors provided in the plurality of subpixels, wherein the first pad electrode is disposed on the same layer as a source electrode and a drain electrode of the plurality of transistors, and the first pad electrode is made of the same material as the source electrode and the drain electrode.

The display device according to an embodiment of the present specification may have a plurality of first pad electrodes that are test pad electrodes.

The display device according to an embodiment of the present disclosure may have a cushion layer made of an organic material.

The display device according to an embodiment of the present disclosure may include a bank disposed between a plurality of light emitting elements.

The display device according to an embodiment of the present disclosure, the thickness of the pad dam may be thicker than the thickness of the planarization layer.

The display device according to an embodiment of the present disclosure may have the pad dam surrounding a periphery of the first pad electrode.

The display device according to an embodiment of the present disclosure further includes a touch sensor disposed on the plurality of light emitting elements of the display area, wherein the touch sensor includes an insulating layer, a plurality of touch electrodes, and a plurality of touch bridge electrodes, the second pad electrode is disposed on the same layer as one of the plurality of touch electrodes and the plurality of touch bridge electrodes, and the second pad electrode is made of the same material as one of the plurality of touch electrodes and the plurality of touch bridge electrodes.

The end of the pad dam of the display device according to an embodiment of the present specification may be closer to the center of the first pad electrode than an end of the planarization layer.

The cushion layer of a display device according to an embodiment of the present specification may be disposed between the first pad electrode, the pad dam, and the second pad electrode.

Although the embodiments of the present disclosure have been described in more detail with reference to the attached drawings, the present disclosure is not necessarily limited to these embodiments, and various modifications may be made without departing from the technical idea of the present disclosure. Accordingly, the embodiments disclosed in the present disclosure are not intended to limit the technical idea of the present disclosure, but to explain it, and the scope of the technical idea of the present disclosure is not limited by these embodiments. Therefore, it should be understood that the embodiments described above are exemplary in all aspects and not restrictive. The protection scope of the present disclosure should be interpreted by the claims, and all technical ideas within a scope equivalent thereto should be interpreted as being included in the scope of the rights of the present disclosure.

According to embodiments of the present disclosure, a cushion layer may be applied to the test pad of the display device to provide the display device that reduces or minimizes damage to the test pad.

According to an embodiment of the present specification, the cushion layer applied to an test pad of a display device prevents cracks from occurring in the test pad during a lighting test, thereby providing a display device with improved corrosion defects occurring after a lighting test.

According to an embodiment of the present specification, a cushion layer applied to an test pad of the display device may prevent panel defects caused by corrosion and cracks, thereby providing the display device with improved yield.

According to an embodiment of the present specification, the display device capable of process optimization may be provided by improving crack occurrence on an test pad of the display device.

The effects of this specification are not limited to the effects mentioned above, and other effects not mentioned will be clearly understood by those skilled in the art from the description below.

The problems to be solved, means for solving the problems, and effects described above do not define the essential features of the disclosure as set forth in the claims, and therefore, the scope of the claims is not limited by the matters described in the specification of the disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a display area in which a plurality of subpixels is arranged and a non-display area adjacent to the display area;
a plurality of light emitting elements provided in the display area;
a first pad electrode on the non-display area of the substrate;
a planarization layer covering an end of the first pad electrode;
a pad dam covering an end of the planarization layer;
a second pad electrode on the first pad electrode, the planarization layer, and the pad dam; and
a cushion layer between the first pad electrode and the second pad electrode

2. The display device of claim 1 further comprising:
a plurality of transistors provided in the plurality of subpixels,
wherein the first pad electrode is on a same layer as a source electrode and a drain electrode of the plurality of transistors, and
wherein the first pad electrode is made of a same material as the source electrode and the drain electrode.

3. The display device of claim 1, wherein the first pad electrode is a test pad electrode.

4. The display device of claim 1, wherein the cushion layer includes an organic material.

5. The display device of claim 1 further comprising:
a bank between the plurality of light emitting elements.

6. The display device of claim 1, wherein a thickness of the pad dam is thicker than a thickness of the planarization layer.

7. The display device of claim 1, wherein the pad dam surrounds a periphery of the first pad electrode.

8. The display device of claim 1 further comprising:
a touch sensor on the plurality of light emitting elements of the display area,
wherein the touch sensor includes an insulating layer, a plurality of touch electrodes, and a plurality of touch bridge electrodes,
wherein the second pad electrode is on a same layer as one of the plurality of touch electrodes and the plurality of touch bridge electrodes, and
wherein the second pad electrode is made of the same material as one of the plurality of touch electrodes and the plurality of touch bridge electrodes.

9. The display device of claim 1,
wherein the end of the first pad electrode is closer to a center of the first pad electrode than the end of the planarization layer.

10. The display device of claim 1, wherein the cushion layer is between the first pad electrode, the pad dam, and the second pad electrode.

11. The display device of claim 1, wherein the cushion layer, in operation, is configured to reduce mechanical stress during a lighting test by increasing a distance between the second pad electrode and the substrate.
